(19) United States
(12) Patent Application Publication
(10) Pub. No.: US 2012/0187455 A1
(43) Pub. Date: Jul. 26, 2012

(54) PHOTOSENSOR AND DISPLAY DEVICE

(75) Inventors: Christopher Brown, Oxford (GB); Kohei Tanaka, Osaka-shi (JP)

(73) Assignee: SHARP KABUSHIKI KAISHA, Osaka-shi (JP)

(21) Appl. No.: 13/383,382

(22) PCT Filed: Jul. 26, 2010
(86) PCT No.: PCT/JP10/62548

§ 371 Date: Jan. 10, 2012

(30) Foreign Application Priority Data
Jul. 28, 2009 (JP) 2009-175161

(51) Int. Cl. H01L 27/148

(52) U.S. Cl. 257/229; 257/E27.15

(57) ABSTRACT

The sensitivity of a photosensor is improved without decreasing read-out efficiency. The photosensor includes: a photodiode (D1) that converts received light into an electric current; a light shielding film (LS) that generates a parasitic capacitance between the photodiode (D1) and itself, a control signal line (RWST) that supplies a storage node (INT) with a reset signal and a read-out signal via the photodiode (D1); and a transistor (M2) connected with the storage node (INT) and an output line (OUT) for outputting, to the output line (OUT), an output signal corresponding to the potential of the storage node (INT) in response to the read-out signal.

REFERENCE TO RELATED APPLICATIONS

This application is the national stage under 35 USC 371 of International Application No. PCT/JP2010/062548, filed Jul. 26, 2010, which claims the priority of Japanese Patent Application No. 2009-175161, filed Jul. 28, 2009, the entire contents of which are incorporated herein by reference.

### TECHNICAL FIELD

The present invention relates to a photosensor having a light detection element such as a photodiode or a phototransistor, and a display device with such a photosensor.

### BACKGROUND ART

A display device with a photosensor including a light detection element such as a photodiode, for example, in a pixel to sense the brightness of external light or capture an image of an object close to the display has been proposed.

In a conventional display device with a photosensor, when well-known components such as signal lines, scan lines, TFTs (thin film transistors) and pixel electrodes are formed by semiconductor processes, photodiodes and other components are formed on the active matrix substrate at the same time (see, for example, JP2006-3857A).

A configuration is also known in which a photosensor formed on the active matrix substrate includes a capacitor that stores an electric current that flow into the photodiode (see, for example, WO2007/145346).

### SUMMARY OF THE INVENTION

To improve the sensitivity of the photosensor in the arrangement of WO2007/145346, the capacitance of the capacitor may be reduced or the size of the photodiode may be increased, for example.

However, reducing the capacitance of the capacitor leads to decreased read-out efficiency, making it difficult to obtain a sufficient output. On the other hand, increasing the size of the photodiode results in an increased parasitic capacitance of the photodiode, leading to decreased read-out efficiency. In other words, there is a trade-off between the sensitivity of a sensor and the read-out efficiency. As such, it was difficult to improve the sensitivity of the sensor without decreasing read-out efficiency.

In view of the foregoing, an object of the present invention is to provide a photosensor where the sensitivity of a photosensor can be improved without decreasing read-out efficiency, and a display device including such a photosensor.

A photosensor according to an embodiment of the present invention includes: a light detection element connected to a storage node to convert received light into an electric current; a conductive film that forms a parasitic capacitance between the light detection element and itself; a control signal line that supplies the storage node, via the light detection element, with a reset signal for resetting a potential of the storage node and a read-out signal for outputting the potential of the storage node; and a switching element connected with the storage node and an output line to output, to the output line, an output signal corresponding to the potential of the storage node in response to the read-out signal.

According to an embodiment of the present invention, the sensitivity of a photosensor can be improved without decreasing read-out efficiency.

### BRIEF DESCRIPTION OF THE DRAWINGS

FIG. 1 is a schematic block diagram of an active matrix substrate included in a liquid crystal display device according to a first embodiment.

FIG. 2 is an equivalent circuit diagram showing the arrangement of a pixel and a photosensor in the pixel region of the active matrix substrate.

FIG. 3 is a diagram showing only the photosensor of the equivalent circuit shown in FIG. 2.

FIG. 4 is a diagram showing a photosensor circuit supplying a reset signal and a read-out signal on separate lines.

FIG. 5A illustrates an example of a signal waveform on the line RWST in the sensor circuit shown in FIGS. 2 and 3.

FIG. 5B illustrates an example of a change in the potential V_{INT} of the storage node in the case of the waveform shown in FIG. 5A.

FIG. 6 is a diagram of an example of the structure of the photosensor shown in FIGS. 2 and 3.

FIG. 7 is a cross sectional view of the portion of the structure shown in FIG. 6 that includes a photodiode.

FIG. 8A is a schematic diagram showing the p, i and n layers in the photodiode in mode A.

FIG. 8B illustrates an energy band in the photodiode in mode A.

FIG. 8C is a diagram showing an equivalent circuit of the photodiode in mode A.

FIG. 9A is a schematic diagram showing the p, i and n layers in the photodiode in mode B.

FIG. 9B illustrates an energy band in the photodiode in mode B.

FIG. 9C is a diagram showing an equivalent circuit of the photodiode in mode B.

FIG. 10 illustrates the ranges of modes A to C.

FIG. 11 is an equivalent circuit diagram of a photosensor according to a second embodiment.

FIG. 12 is a diagram of a photosensor circuit where the potential of the storage node is boosted up and amplified during read-out with only a variable capacitance.

FIG. 13 is a diagram of an example of the structure of the photosensor shown in FIG. 11.

### DETAILED DESCRIPTION OF THE INVENTION

A photosensor according to an embodiment of the present invention includes: a light detection element connected to a storage node to convert received light into an electric current; a conductive film that forms a parasitic capacitance between the light detection element and itself; a control signal line that supplies the storage node, via the light detection element, with a reset signal for resetting a potential of the storage node and a read-out signal for outputting the potential of the storage node; and a switching element connected with the storage node and an output line to output, to the output line, an output signal corresponding to the potential of the storage node in response to the read-out signal (first arrangement).

In the above arrangement, the control signal line supplies a reset signal and a read-out signal to the storage node via the light detection element. Thus, the charge accumulated in the parasitic capacitance of the light detection element from the time when the supply of reset signals is finished until a read-out signal is supplied can be reflected in the potential of the storage node during read-out. Such an arrangement that reads out the charge of the parasitic capacitance in the light detection element will reduce the capacitance in the entire photosensor. Thus, the sensitivity of the sensor will be improved without decreasing read-out efficiency. Moreover, in the above arrangement, no capacitance needs to be provided, reducing the number of parts.

Further, such an arrangement that supplies a reset signal and a read-out signal on the control signal line will reduce the number of lines required for the photosensor, thereby simplifying the arrangement of the circuit. Thus, the aperture ratio will be improved.

In the first arrangement, the light detection element may be a photodiode having a cathode connected with the control signal line and an anode connected with the storage node (second arrangement). Thus, a reset signal and a read-out signal can be supplied from the control signal line to the storage node via a photodiode, which is a light detection element. Accordingly, the number of lines required for the photosensor will be reduced, thereby simplifying the circuit. Thus, the aperture ratio will be improved.

In the first or second arrangement, the light detection element may be a photodiode; the photodiode may include a silicon film provided above the conductive film to be electrically insulated from the conductive film; and a p-type semiconductor region, an intrinsic semiconductor region and an n-type semiconductor region may be provided adjacent to one another along a surface of the silicon film in the silicon film (third arrangement).

In the above arrangement, the parasitic capacitance between the silicon film including the p-type semiconductor region, the intrinsic semiconductor region and the n-type semiconductor region, and the conductive film increases in accordance with the amount of received light. Thus, the sensitivity of the sensor will be further improved.

In any one of the first to third arrangements, an amplifying element provided between the storage node and the switching element may further be included to amplify the potential of the storage node in accordance with the read-out signal. The amplifying element amplifying the potential of the storage node during read-out will further improve the sensitivity of the sensor (fourth arrangement).

In any one of the first to fourth arrangements, it is preferable that at least a voltage level of the reset signal, a voltage level for reverse-biasing the light detection element from the reset signal until the read-out signal and a voltage level of the read-out signal are set as voltage levels on the control signal line (fifth arrangement). These three voltage levels being set as voltage levels on the control signal line will allow a storage node to be reset and read out via the light detection element efficiently using one line.

In any one of the first to fifth arrangements, it is preferable that, when the reset signal is supplied, the potential of the storage node is initialized and, when the supply of the reset signal is finished, the light detection element is reverse-biased; when the read-out signal is supplied, the potential of the storage node changed by a charge accumulated in the parasitic capacitance of the light detection element from the time when the supply of the reset signal is finished until the read-out signal is supplied is boosted up; and the potential of the storage node is boosted up by the read-out signal and thus the switching element becomes conductive to output, to the output line, an output signal corresponding to the potential of the storage node (sixth arrangement).

In the above arrangement, the signal from the control signal line will enable reading the charge accumulated in the parasitic capacitance of the light detection element from the time when the supply of a reset signal is finished until a read-out signal is supplied and outputting it to the output circuit.

In any one of the first to sixth arrangements, it is preferable that the conductive film is a light shielding film for the light detection element (seventh arrangement).

Thus, the conductive film also serves as a light shielding film, thereby simplifying the structure of the light sensor. Moreover, as discussed above, parasitic capacitance is formed between the conductive film and the light detection element, thereby eliminating the need for a capacitor.

A display device including a photosensor of any one of the first to seventh arrangements in the pixel region of the active matrix substrate is also one example of an embodiment of the present invention (eighth arrangement). Thus, a display device having a photosensor with improved sensitivity will be realized. Further, in the above photosensor, both the reset signal and the read-out signal are supplied from the control signal line, thus having a smaller number of lines than in an arrangement where a reset signal and a read-out signal are supplied on separate lines. Providing such a photosensor in the pixel region will increase the aperture ratio of the pixel region of the display device. It should be noted that the display device may further include: a counter substrate opposite the active matrix substrate; and liquid crystal sandwiched by the active matrix substrate and the counter substrate (ninth arrangement).

An embodiment of the present invention will now be described referring to the drawings. While the embodiment below illustrates an arrangement where a display device according to an embodiment of the present invention is implemented as a liquid crystal display device, the display device according to the embodiment of the present invention is not limited to the liquid crystal display device and may be employed in any display device using an active matrix substrate. It should be noted that the display device according to the embodiment of the present invention may be utilized as a display device with a touch panel that has a photosensor to detect an object close to the screen to allow input operations, or a bidirectional communication display device including display and image-capturing functionality.

For purposes of explanation, the drawings referred to below only show the components of the embodiment that are relevant and necessary for the description, in a simplified fashion. Accordingly the display device according to the embodiment of the present invention may include a desired component not shown in the drawings referred to in the present specification. Further, the sizes of the parts in the drawings do not exactly represent the sizes of the actual components and the size ratios of the parts.

### First Embodiment

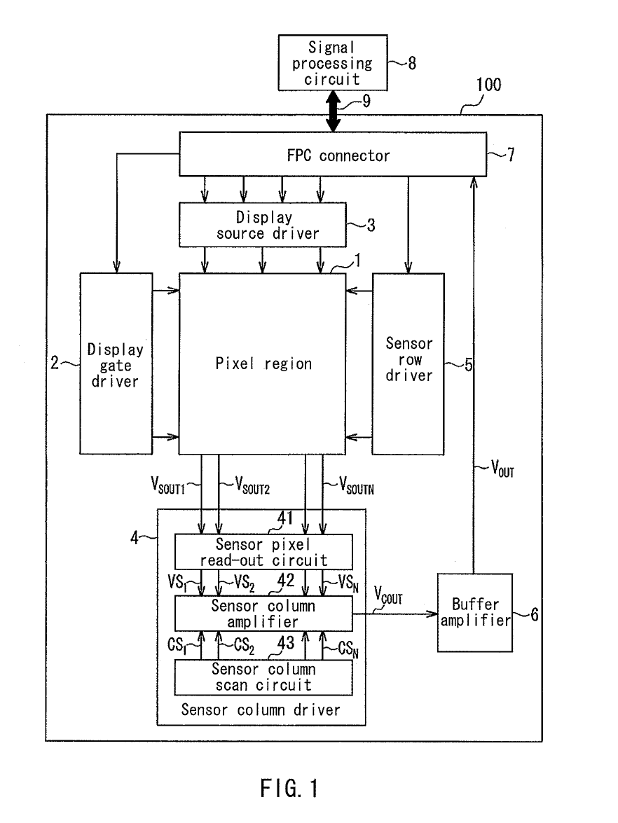

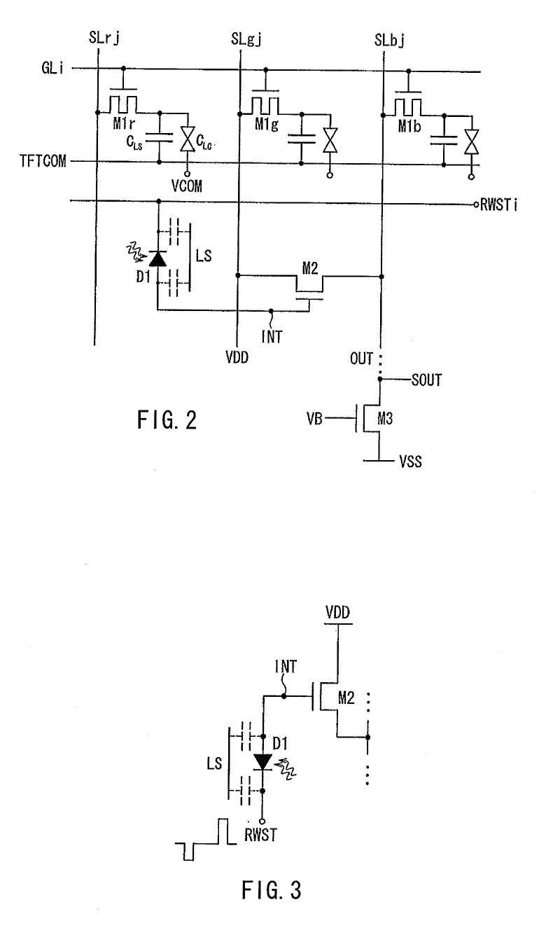

First, referring to FIGS. 1 and 2, the configuration of an active matrix substrate included in a liquid crystal display device according to a first embodiment will be described.

### Configuration of Active Matrix Substrate

FIG. 1 is a schematic block diagram of an active matrix substrate 100 included in a liquid crystal display device according to a first embodiment. As shown in FIG. 1, the active matrix substrate 100 includes, on a glass substrate, at least, a pixel region 1, a display gate driver 2, a display source driver 3, a sensor column driver 4, a sensor row driver 5, a buffer amplifier 6 and an FPC connector 7. Also, a signal processing circuit 8 for processing an image signal captured by a photosensor (described below) in the pixel region 1 is connected with the active matrix substrate 100 via the FPC connector 7 and the FPC 9.

The sensor column driver 4 includes a sensor pixel read-out circuit 41, a sensor column amplifier 42 and a sensor column scan circuit 43. An output line SOUT (see FIG. 2) for outputting a sensor output V_{SOUT} from the pixel region 1 is connected with the sensor pixel read-out circuit 41. Sensor outputs from the output line SOUTj (j=1 to N) are labeled V_{SOUT1} to V_{SOUTN} in FIG. 1. The sensor pixel read-out circuit 41 outputs peak hold voltages VSⱼ (j=1 to N) of the sensor outputs V_{SOUT}ⱼ (j=1 to N) to the sensor column amplifier 42.

The sensor column amplifier 42 incorporates N column amplifiers corresponding to the N rows of photosensors in the pixel region 1. The sensor column amplifier 42 amplifies the peak hold voltages VSⱼ (j=1 to N) in its column amplifiers and outputs them as V_{COUT} to the buffer amplifier 6. The sensor column scan circuit 43 outputs the column select signals CSⱼ (j=1 to N) to the sensor column amplifier 42 to sequentially connect the column amplifiers of the sensor column amplifier 42 with the outputs to the buffer amplifier 6. The buffer amplifier 6 further amplifies V_{COUT} output from the sensor column amplifier 42 and outputs it as a panel output Vₒᵤₜ to the signal processing circuit 8 via the FPC connector 7.

The components of the active matrix substrate 100 above may also be formed monolithically on a glass substrate using a semiconductor process. Alternatively, the amplifiers or drivers above may be mounted on a glass substrate using a COG (chip-on glass) technique, for example. Alternatively, at least some of the components of the active matrix substrate 100 shown in FIG. 1 may be mounted on the FPC 9. The active matrix substrate 100 is opposite a counter substrate (not shown) including a common electrode on its entire surface to form a gap between the counter substrate and itself. The gap is filled with liquid crystal material. A backlight (not shown) may be provided on the backside of the active matrix substrate 100.

### Configuration of Display Circuit

The pixel region 1 includes a plurality of pixels to display an image. In the present embodiment, a photosensor for capturing an image is provided in each pixel in the pixel region 1. FIG. 2 is an equivalent circuit diagram showing the arrangement of a pixel and a photosensor in the pixel region 1 of the active matrix substrate 100. In the implementation of FIG. 2, one pixel is composed of three subpixels of different colors: R (red), G (green) and B (blue). One photosensor is provided in one pixel composed of those three subpixels. The pixel region 1 includes pixels arranged in a matrix of M rows and N columns and photosensors arranged in a similar matrix of M rows and N columns. As discussed above, one pixel is composed of three subpixels, and thus the number of subpixels is M×3N.

As shown in FIG. 2, the pixel region 1 includes gate lines GL and source lines SL arranged in a matrix as the lines for the pixels. The gate lines GL are connected with the display gate driver 2. The source lines SL are connected with the display source driver 3. M rows of gate lines GL are provided in the pixel region 1. In the description below, when each gate line GL needs to be described separately, it is referred to as GLi (i=1 to M). Meanwhile, three source lines SL are provided in one pixel in order to supply the three subpixels in one pixel with image data, as discussed above. In the description below, when each source line SL needs to be described separately, it is referred to as SLrj, SLgj or SLbj (j=1 to N).

A thin film transistor (TFT) M1 is provided as a switching element for the pixel at the intersection of a gate line GL and a source line SL. In FIG. 2, thin film transistors M1 provided in their respective subpixels for red, green and blue are labeled M1r, M1g and M1b. A thin film transistor M1 has a gate electrode connected with a gate line GL, a source electrode connected with a source line SL, and a drain electrode connected with a pixel electrode, not shown. Thus, as shown in FIG. 2, a liquid crystal capacitance C_{LC} is formed between the drain electrode of the thin film transistor M1 and the common electrode (VCOM). Further, an auxiliary capacitance C_{LS} is formed between the drain electrode and the TFTCOM.

In FIG. 2, the subpixel driven by the thin film transistor M1r connected with the intersection of one gate line GLi and one source line SLrj has a red color filter that corresponds to this subpixel. The subpixel functions as a red subpixel as image data for red is supplied by the display source driver 3 via the source line SLrj.

Further, the subpixel driven by the thin film transistor M1g connected with the intersection of a gate line GLi and a source line SLgj has a green color filter that corresponds to this subpixel. The subpixel functions as a green subpixel as image data for green is supplied by the display source driver 3 via the source line SLgj.

Furthermore, the subpixel driven by the thin film transistor M1b connected with the intersection of a gate line GLi and a source line SLbj has a blue color filter that corresponds to this subpixel. The subpixel functions as a blue subpixel as image data for blue is supplied by the display source driver 3 via the source line SLbj.

In the implementation of FIG. 2, one photosensor is provided for one pixel (i.e. three subpixels) in the pixel region 1. However, the ratio of the number of photosensors relative to that of pixels is not limited to the present embodiment and thus is arbitrary. For example, one photosensor may be provided for one subpixel, or one photosensor may be provided for a plurality of pixels.

### Configuration of Photosensor Circuit

As shown in FIG. 2, a photosensor includes a photodiode D1, which is an example of a light detection element, and a transistor M2, which is an example of a switching element. A light shielding film LS (conductive film) for preventing backlight from entering the photodiode D1 is provided on the backside of the photodiode D1. In other words, a light shielding film LS is provided to block light directed to the backside of the photodiode D1. The light shielding film LS is made of a metal film, for example, and is electrically insulated from other parts. Thus, a parasitic capacitance is formed between the photodiode D1 and the light shielding film LS.

The photodiode D1 has a cathode connected with a line RWST (control signal line) for supplying a reset signal and a read-out signal. The photodiode D1 has an anode connected with the gate of the transistor M2. In the implementation of FIG. 2, the node on the line connecting the photodiode D1 with the gate of the transistor M2 is referred to as a storage node INT. The transistor M2 has a drain connected with the line VDD and a source connected with the line OUT. The line VDD is a line for supplying a constant voltage V_{DD} to the photosensor, while the line OUT is an example of an output line for outputting an output signal from the photosensor.

FIG. 3 is a diagram showing only the photosensor of the equivalent circuit shown in FIG. 2. In the circuit configuration shown in FIGS. 2 and 3, a reset signal is supplied from the line RWST and the storage node INT is initialized. When a read-out signal is supplied from the line RWST to the storage node INT via the photodiode D1, the potential V_{INT} of the storage node INT is boosted up and the transistor M2 becomes conductive. Thus, an output signal corresponding to the potential VINT of the storage node INT is output to the line OUT. At this time, the amount of current in accordance with the amount of received light flows into the photodiode D1 during a period starting from the end of the supply of a reset signal until the beginning of the supply of a read-out signal (sensing period), and the charge in accordance with this amount of current is accumulated in the parasitic capacitance. Therefore, during the supply of a read-out signal, the potential V_{INT} of the storage node INT varies in accordance with the amount of current that has flown into the photodiode D1. An output signal corresponding to the potential V_{INT} of the storage node INT is output to the line OUT, and thus the amount of light received by the photodiode D1 is reflected in the output signal.

In the configuration shown in FIG. 3, during the reset period, the line RWST supplies a first voltage (i.e. a reset signal) for reverse-biasing the photodiode D1 and setting the potential V_{INT} of the storage node INT to a predetermined initial value. During the sensing period, the line RWST supplies a second voltage for reverse-biasing the photodiode D1. Then, during the read-out period, the line RWST supplies a third voltage (i.e. a read-out signal) for making the transistor M2 connected with the storage node INT conductive. Thus, signals controlling resetting, sensing and reading-out are supplied by the line RWST, resulting in a smaller number of lines than in an arrangement where a reset signal and a read-out signal are supplied on different lines.

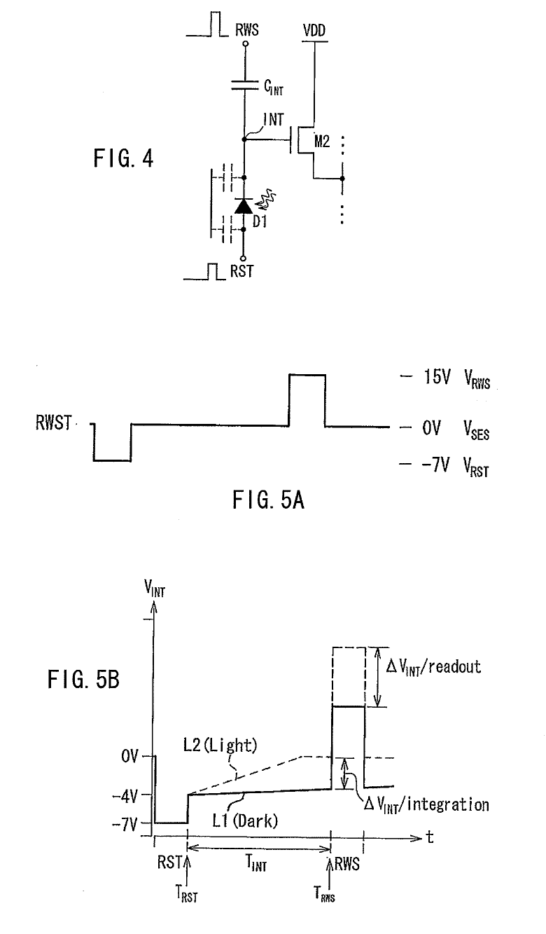

FIG. 4 is a diagram showing a photosensor circuit supplying a reset signal and a read-out signal on separate lines. In the implementation shown in FIG. 4, a reset signal is supplied from a line RST and a read-out signal is supplied from a line RWS. The sensor circuit shown in FIG. 3 does not need a capacitor C_{INT} (i.e. capacitor-less), thus requiring a smaller number of elements of the circuit than an arrangement where a capacitor C_{INT} is provided between the photodiode D1 and the line RWS, as in FIG. 4. Further, since the sensor circuit shown in FIG. 3 does not have a capacitor C_{INT}, the entire sensor circuit has a smaller capacitance C_{T}. Thus, the sensitivity of the sensor will be improved.

FIG. 2 shows a configuration where the sensor circuit shown in FIG. 3 described above is incorporated into the pixel region 1 of the liquid crystal display device. In the implementation shown in FIG. 2, the source line SLg also serves as a line VDD for supplying the constant voltage VDD from the sensor column driver 4 to the photosensor. Further, the source line SLb also serves as a line OUT for sensor output. The line RWST is connected with the sensor row driver 5. Since a line RWST is provided for each row, when each line needs to be described separately in the description below, it is labeled RWSTi (i=1 to M).

The sensor row driver 5 sequentially selects a line RWSTi shown in FIG. 2 in a predetermined time interval t_{row}. Thus, a row of photosensors where the signal charge is to be read out is sequentially selected in the pixel region 1.

As shown in FIG. 2, the end of the line OUT is connected with the drain of the transistor M3. The transistor M3 may be, for example, an insulated gate field-effect transistor. An output line SOUT is also connected with the drain of the transistor M3. Thus, the potential V_{SOUT} of the drain of the transistor M3 is output to the sensor column driver 4 as an output signal from the photosensor. The source of the transistor M3 is connected with the line VSS. The gate of the transistor M3 is connected with a reference voltage supply (not shown) via a reference voltage line VB.

### Example of Operation of Photosensor

FIG. 5A illustrates an example of a signal waveform on the line RWST in the sensor circuit shown in FIGS. 2 and 3. FIG. 5B illustrates an example of a change in the potential V_{INT} on the storage node INT in the case of the waveform shown in FIG. 5A. In the implementation shown in FIG. 5A, after a pulse of the voltage V_{RST} (reset signal) is applied to the line RWST, the voltage on the line RWST returns to the voltage V_{SES}. Thereafter, a pulse voltage of the voltage V_{RWS} (read-out signal) is applied to the line RWST. In the implementation of FIG. 5A, the voltage V_{RST} of a reset signal may be −7 volts, and the voltage V_{SES} may be 0 volts, although they are mere examples. The voltage V_{RWS} of the read-out signal may be 15 volts.

First, when a reset signal of the voltage V_{RST} is supplied to the line RWST, the photodiode D1 is forward-biased and the potential V_{INT} of the storage node INT is initialized. The potential V_{INT} of the storage node INT is expressed by the following Equation (1):

V_{INT}=V_{RST}+V_{F} (1)

In Equation (1), VF is a forward voltage of the photodiode D1. V_{INT} at this time is lower than the threshold voltage of the transistor M2, such that the transistor M2 is non-conductive after the reset.

Next, at the time t=T_{RST}, the voltage on the line RWST returns to V_{SES} and the supply of a reset signal is finished. The voltage on the line RWST returning to V_{SES} causes the photodiode D1 to be reverse-biased, and the integration period of current (sensing period: T_{INT}) begins. During this sensing period, the amount of current in accordance with the amount of light that has entered the photodiode D1 flows to charge the parasitic capacitance. Thus, the potential V_{INT} of the gate of the transistor M2 when the sensing period is finished is expressed by Equation (2) below. During the sensing period, too, V_{INT} is lower than the threshold voltage of the transistor M2, such that the transistor M2 is non-conductive.

V_{INT}=V_{RST}+V_{F}+ΔV_{RST}·C_{PD}/C_{T}+I_{PHOTO}·T_{INT}/C_{T} (2)

In Equation (2), ΔV_{RST} is the height of the pulse of a reset signal (|V_{SES}−V_{RST}|). I_{PHOTO} is the light current of the photodiode D1, and T_{INT} is the length of the sensing period. C_{PD} is the capacitance of the photodiode D1 (for example, the sum of the parasitic capacitance between the photodiode D1 and the light shielding film LS). C_{T} is the sum of the capacitance C_{PD} of the photodiode D1 and the capacitance C_{TFT} of the transistor M2. The fourth term in Equation (2) above, I_{PHOTO}·T_{INT}/CT, represents the amount of variation of the potential V_{INT} of the storage node INT due to the current that has flown into the photodiode D1 during the sensing period T_{INT}.

Since the photosensor of the present embodiment is configured to reduce C_{T}, the amount of variation of V_{INT} in response to the light current I_{PHOTO} is increased. As a result, the sensitivity of the photosensor is improved. For example, in the arrangement of the present embodiment, which does not include a capacitor C_{INT}, the entire capacitance C_{T} is smaller than in the arrangement with a capacitor C_{INT} as shown in FIG. 4, thereby improving the sensitivity of the photosensor.

At the time when the sensing period ends, i.e. t=T_{RWS}, a read-out signal rises. Thus, the read-out period begins. The read-out period continues while the voltage V_{RWS} is being supplied from the line RWST. During the read-out period, the potential V_{INT} of the storage node INT is boosted up by the voltage V_{RWS} supplied from the line RWST. As a result, the potential V_{INT} of the storage node INT is expressed by the following Equation (3):

V_{INT}=V_{RST}+V_{F}+ΔV_{RST}·C_{PD}/C_{T}+I_{PHOTO}·T_{INT}/C_{T}+ΔV_{RWS}·C_{PD}/C_{T} (3)

ΔV_{RWS} is the height of the pulse of a read-out signal (|V_{RWS}−V_{SES}|). When the potential V_{INT} of the storage node INT becomes higher than the threshold voltage of the transistor M2 due to a reset signal, the transistor M2 becomes conductive. When the transistor M2 becomes conductive, it functions as a source follower amplifier together with the transistor M3 provided at the end of the line OUT in each column. In the photosensor according to the present embodiment, the signal voltage output from the output line SOUT via the drain of the transistor M3 corresponds to the value of integral of the light current of the photodiode D1 during the sensing period.

In FIG. 5B, the waveform L1 indicated by a solid line represents variations in the potential V_{INT} when no light enters the photodiode D1. The waveform L2, indicated by a broken line, represents variations in the potential V_{INT} when light at a saturation level enters the photodiode D1. In the example shown in FIG. 5B, during the sensing period T_{INT}, the potential V_{INT} of the storage node INT increases as the light current of the photodiode D1 increases, and is saturated at 0 volts. ΔV_{INT}/readout is the amount of boost-up in the potential V_{INT} due to a read-out signal applied from the line RWST during the read-out period. ΔV_{INT}/integration is the value of integral of the light current of the photodiode D1 during the sensing period.

### Configuration of Sensor Circuit

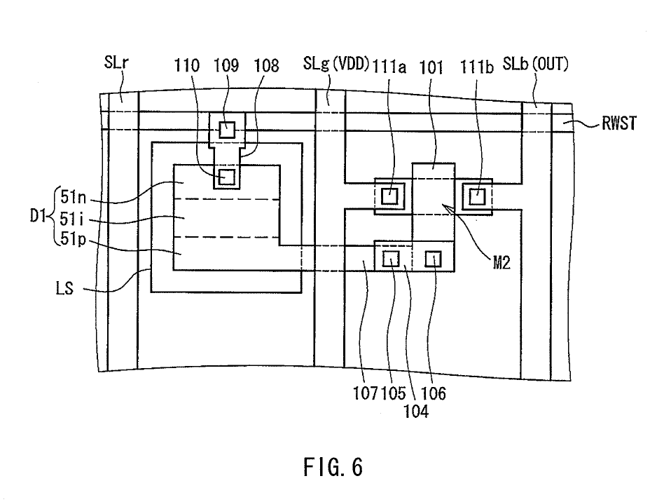

FIG. 6 is a diagram of an example of the structure of the photosensor shown in FIGS. 2 and 3. In an implementation shown in FIG. 6, the photosensor includes source metal that forms the source lines SLr, SLg and SLb on the active matrix substrate and gate metal that forms the line RWST that lies perpendicular to the source metal. The source metal and the gate metal are formed as different layers separated by an insulating film. In the implementation shown in FIG. 6, the gate metal is formed below the layer of source metal. The source line SLg also serves as a line VDD, and the source line SLb also serves as a line OUT.

A photodiode D1 is provided in the area sandwiched by the source line SLr and the source line SLg. A transistor M2 is provided in the area sandwiched by the source line SLg and the source line SLb.

The photodiode D1 is a lateral PIN diode having a p-type semiconductor region 51p, an i-type semiconductor region 51i and a n-type semiconductor region 51n formed in series in a silicon film that forms the base (described in detail below). A light shielding film LS for preventing illumination light from the backlight from entering the photodiode D1 is provided on the backside of the photodiode D1. The n-type semiconductor region 51n forms the cathode of the photodiode D1. The n-type semiconductor region 51n is connected with the line RWST via the line 108 and contact holes 109 and 110. The p-type semiconductor region 51p forms the anode of the photodiode D1. The p-type semiconductor region 51p is connected with the gate electrode 101 of the transistor M2 via an extension 107 of the silicon film, contact holes 105 and 106 and a line 104. The transistor M2 includes a gate electrode 101 and an electrode including a source electrode 111b and a drain electrode 111a and having a portion lying over the gate electrode 101.

In the arrangement shown in FIG. 6, only one line, i.e. the line RWST, is used to drive the photosensor. Consequently, in the arrangement shown in FIG. 6, the number of lines added for the photosensor is reduced, thereby simplifying the circuit. As a result, the aperture ratio in the pixel region 1 is improved.

### Configuration of Photodiode

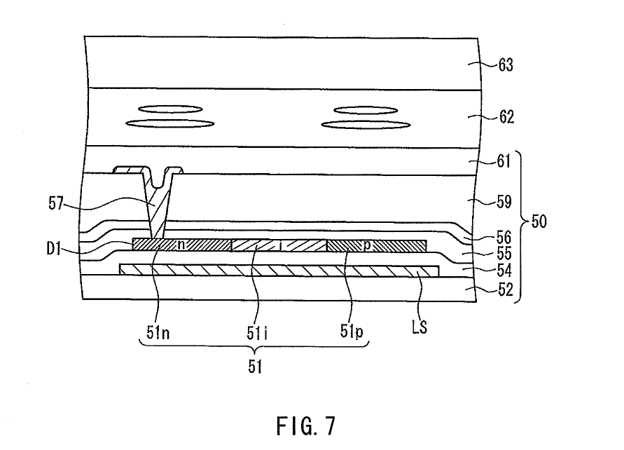

Next, a preferred arrangement of the photodiode will be described. FIG. 7 is a cross sectional view of the photosensor including the photodiode D1 shown in FIG. 6. In the implementation shown in FIG. 7, the light shielding film LS, which is a metal film, is provided on the major surface of the light-permeable base substrate 52. The photodiode D1 is formed above the light shielding film LS. In the implementation shown in FIG. 7, the base substrate 52 is part of the active matrix substrate 100. The light shielding film LS is electrically insulated from the other components and is electrically floating.

Further, as shown in FIGS. 6 and 7, the photodiode D1 includes a silicon film 51 having a semiconductor region. The silicon film 51 is formed on the insulating film 54 that covers the light shielding film LS, and is electrically insulated from the light shielding film LS. In the silicon film 51, the n-type semiconductor region (n layer) 51n, the intrinsic semiconductor region (i layer) 51i and the p-type semiconductor region (p layer) 51p are formed in this order along the film surface. The i layer 51i is the light detection region of the photodiode D1. The n layer 51n, the i layer 51i and the p layer 51p are formed next to each other along the surface of the silicon film 51.

Suitably, the i layer 51i is electrically neutral with respect to the adjacent n layer 51n and p layer 51p. Preferably, the i layer 51i is a region including no impurities or a region in which the conduction electron density is equal to the hole density. However, the i layer 51i may also be a n-region with a lower diffusive concentration of the n-type impurities than in the n layer 51n, or a p-region with a lower diffusive concentration of the p-type impurities than in the p layer 51p. In other words, the intrinsic semiconductor region of the present embodiment includes the n-region and the p-region.

In the present embodiment, the silicon forming the silicon film 51 is not limited to any particular type. However, it is preferable that the silicon 51 is formed by a consecutive crystal grain boundary silicon or low temperature polysilicon from the viewpoint of charge movement speed. Further, the silicon film 51 may be formed on the base substrate 52 of the active matrix substrate utilizing the process of forming thin film transistors (TFTs) that function as active elements, at the same time as these transistors.

In the implementation shown in FIG. 7, an interlayer insulating films 55 and 56, a planarizing film 59 and a protection film 61 are provided on the photodiode D1. A contact hole 57 that penetrates the interlayer insulating films 55 and 56 and the planarizing film 59 is connected with the n layer 51n. A counter substrate 63 (only shown in its outer shape) is provided on the protection film 61 with an interposed liquid crystal layer 62.

The use of a lateral photodiode D1 as shown in FIGS. 6 and 7 further improves sensitivity due to a change in diode properties. That is, the total amount CPD of the parasitic capacitance between the lateral photodiode D1 and the light shielding film LS is small when the amount of received light is small, and increases as the amount of received light increases and comes close to saturation. Consequently, the boost-up capacitance when the amount of received light is close to saturation or has reached saturation (bright state) is larger than the boost-up capacitance when there is almost no received light (dark state). As a result, when the amount of received light of the photodiode D1 during the sensing period is above a predetermined value, the amount of the potential V_{INT} of the storage node INT boosted up by a read-out signal (the term (ΔV_{RWS}·C_{PD}/CT) in Equation (3) above) is amplified. Thus, the sensitivity of the photosensor is improved. The following discusses the reasons why this effect occurs.

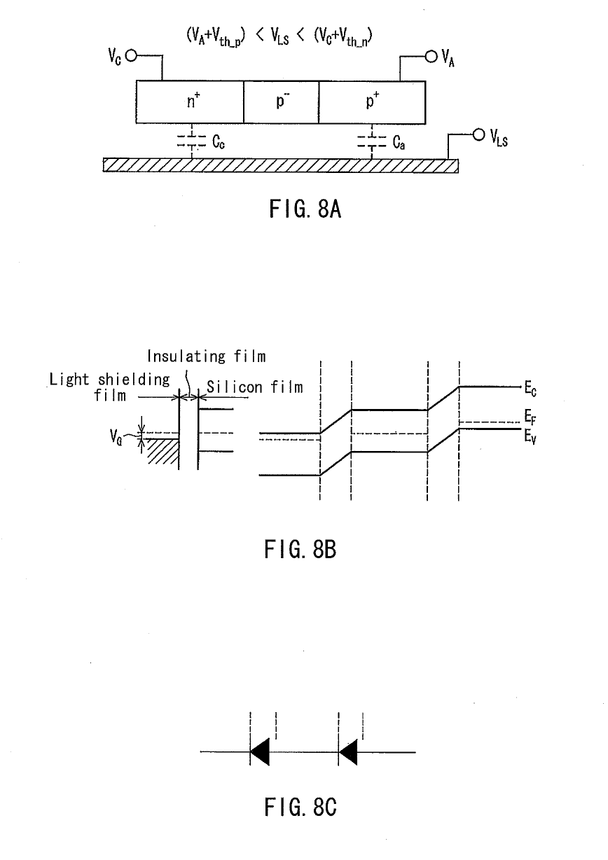

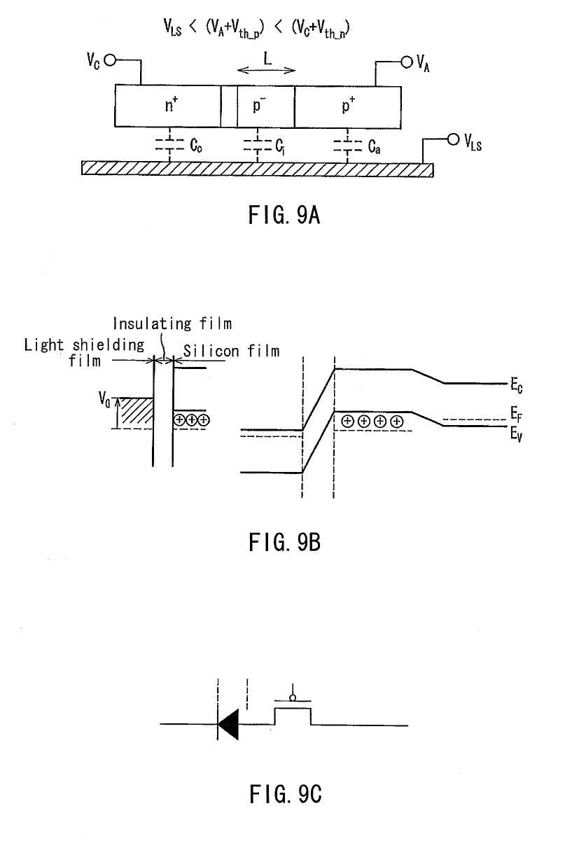

FIGS. 8 and 9 show relationships between the potential V_{LS} of the light shielding film LS and the conditions of the photodiode D1. FIG. 8 shows the photodiode D1 directly after the integration period starts (directly after V_{INT} is initialized and the photodiode D1 is reverse-biased), while FIG. 9 shows the photodiode D1 when a read-out signal is supplied. FIGS. 8A and 9A schematically show the p, i and n layers in the photodiode D1. FIGS. 8B and 9B show energy bands in the photodiode D1, while FIGS. 8C and 9C show equivalent circuits.

The potential V_{LS} of the light shielding film LS satisfies Equation (4) below directly after a reset signal is supplied, as shown in FIG. 8, and satisfies Equation (5) below when a read-out signal is supplied, as shown in FIG. 9.

(V_{A}+Vₜₕ_{_{—p}})<V_{LS}<(V_{C}+Vₜₕ_{_{—n}}) (4)

V_{LS}<(V_{A}+Vₜₕ_{_{—p}})<(VC+Vₜₕ_{_{—n}}) (5)

Here, Vc represents the potential of the n layer 51n in the photodiode D1, and VA represents the potential of the p layer 51p of the photodiode D1. Vₜₕ_{_{—n}} represents a threshold voltage supposing an n-channel MOS transistor in which the n layer 51n is the source-drain region, the light shielding film LS is the gate electrode and the insulating film 54 is the gate insulating film. Similarly, Vₜₕ_{_{—p}} represents a threshold voltage supposing a p-channel MOS transistor in which the p layer 51p is the source-drain region, the light shielding film LS is the gate electrode and the insulating film 54 is the gate insulating film. E_{C} represents energy level in the conduction band, E_{F} represents energy level in the forbidden band and Ev represents energy level in the valence band.

If, as shown in FIGS. 8A and 8B, the voltage V_{LS} of the light shielding film LS satisfies Equation (4) above (hereinafter referred to as “mode A”), free electrons and holes tend to move near the both interfaces of the i layer 51i. In mode A, as shown in FIG. 8C, a current can flow smoothly through the photodiode D1. In this case, the capacitance CPD between the entire photodiode D1 and the light shielding film LS is the capacitance Ca between the p layer 51p and the light shielding film LS series-coupled with the capacitance Cc between the n layer 51n and the light shielding film LS. For example, CPD may be expressed by the Equation (C_{PD}=Ca·Cc/(Ca+Cc)).

If, as shown in FIGS. 9A and 9B, the potential V_{LS} of the light shielding film LS satisfies Equation (5) above (hereinafter referred to as “mode B”), free electrons and holes tend to move in the i layer 51i only near the interface between it and the n layer 51n. In mode B, as shown in FIG. 9C, the flow of current is blocked by the i layer 51b. Moreover, in mode B, as shown in FIG. 9A, a portion of the i layer 51i is inverted to be a p layer such that, in effect, the area of the p layer 51p is increased. The length L of the inverted portion in the direction in which the p, i and n layers are arranged will be hereinafter referred to as the “inversion length”. A capacitance Ci is generated between the inverted portion of the i layer 51i and the light shielding film LS. The capacitance C_{PD} between the entire photodiode D1 and the light shielding film LS is the sum of the capacitance Ca and the capacitance Ci, (Ca+Ci), series-coupled with Cc. For example, the capacitance CPD may be expressed by the Equation

(C_{PD}=(Ca+Ci)·Cc/(Ca+Ci+Cc)).

Thus, if a light current of the photodiode D1 flows during a sensing period and the potential V_{INT} of the storage node INT exceeds a predetermined value and the device transitions to mode B, a portion of the i layer 51i is inverted to increase the capacitance C_{PD}. Thus, the boost-up capacitance due to a read-out signal is increased. Consequently, the potential V_{INT} during read-out is amplified. On the other hand, if the amount of received light during a sensing period is small and thus the device does not transition into mode B, the capacitance C_{PD} is not large enough to cause the potential V_{INT} to be amplified by an increase in the boost-up capacitance during read-out. Thus, there is a large difference in the potential V_{INT} during read-out between the dark state, where the amount of received light during the sensing period is small, and the bright state, where the amount of received light is saturated or comes close to saturation, thereby improving sensitivity.

Further, if the device transitions into mode B, the inversion length L becomes larger and the capacitance C_{PD} becomes larger as the amount of received light increases and the potential V_{INT} of the storage node INT increases, as discussed below. Thus, the boost-up capacitance due to a read-out signal becomes larger, increasing the amount of amplification of the potential V_{INT} during read-out. As a result, sensitivity is further improved.

In mode B, the inversion length L depends on the potential V_{LS} of the light shielding film LS during read-out. Since the potential V_{LS} varies depending on the potential V_{INT} of the storage node, the inversion length L during read-out varies depending on the potential V_{LS} during read-out, or the potential V_{INT}.

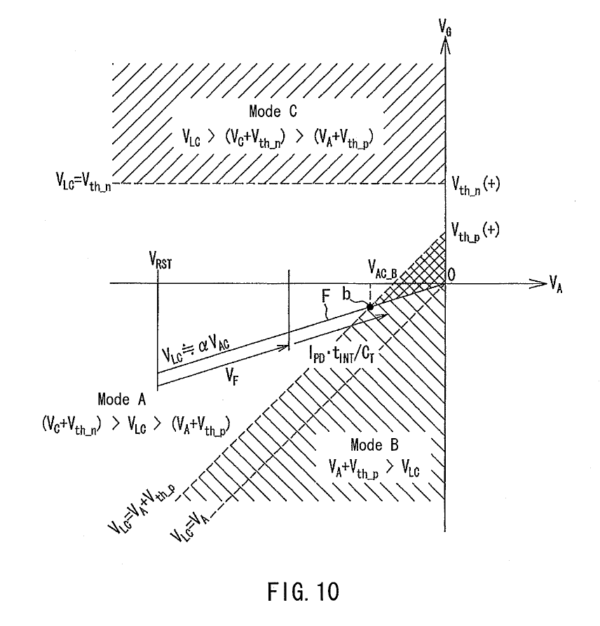

FIG. 10 illustrates the ranges of modes A to C. In FIG. 10, the vertical axis represents the potential V_{LS} of the light shielding film LS, while the horizontal axis represents the potential difference V_{AC} between the p layer 51p and the n layer 51n (the potential difference between the anode and the cathode). The straight line F in FIG. 10 indicates the relationship between the potential V_{LS} and the potential difference VAC occurring when the photodiode D1 receives light during a sensing period to cause a light current to flow until it reaches saturation. In the implementation shown in FIG. 10, the potential V_{LS} is approximated by Equation (6) below using the potential difference V_{AC}.

[Formula 1]

V_{LS}≈αV_{AC} (6)

Here, α=(Ca/Cc+Ca). It should be noted that in mode B, as shown in FIG. 9A, the area of the p layer 51p is increased, in effect, such that the value of Ca is larger (i.e. Ca+Ci) than in mode A. Thus, the value of a is larger in mode B, such that the straight line expressed by Equation (6) above is steeper than in mode A. In the example shown in FIG. 10, as the potential difference V_{AC} initialized by a reset signal to V_{RST} decreases due to VF and the potential variation due to light current (I_{PHOTO}·T_{INT}/C_{T}) as indicated by the straight line F, V_{LS} comes closer to a predetermined value (0 volts). Then, at the intersection b between the straight line F and the straight line V_{LC}=V_{A}+Vₜₕ_{_{—p}}, the photodiode D1 transitions into mode B. That is, the device transitions into mode B when the potential difference V_{AC} between the anode and the cathode becomes smaller than the value V_{AC}_{_{—}}B of V_{AC} at point b. In mode B, the capacitance C_{PD} varies depending on the inversion length L. Thus, after the device transitions into mode B, the inversion length L becomes larger by the increase in received light, increasing the capacitance C_{PD}. The boost-up amount in the potential VINT due to a read-out signal is amplified depending on the capacitance C_{PD}. Thus, sensitivity is improved.

Mode C shown in FIG. 10 is the mode of the photodiode D1 when the potential V_{LS} of the light shielding film LS satisfies Equation (7) below. In mode C, free electrons and holes tend to move in the i layer 51i near the interface between it and the p layer 51p.

(V_{A}+Vₜₕ_{_{—p}})<(V_{C}+Vₜₕ_{_{—n}})<V_{LS} (7)

It should be noted that the discussions above are based on one aspect of the characteristics of a photodiode, and is not intended to exclude the possibility of explaining the improvements in sensitivity from different perspectives. Further, FIG. 10 merely shows one example and thus, in reality, the ranges of modes A, B and C and the straight F differ depending on the structure of the photodiode D1 and the light shielding film LS, for example.

### Second Embodiment

### Circuit Configuration of Photosensor

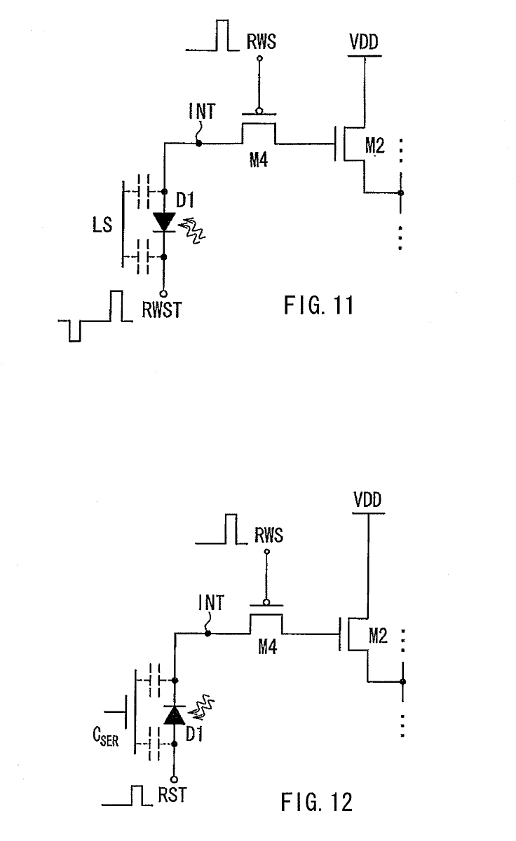

FIG. 11 is an equivalent circuit diagram of a photosensor according to a second embodiment. In the implementation shown in FIG. 11, a p-channel transistor M4 which is an example of an amplifying element (hereinafter referred to as the transistor M4) is connected between the photodiode D1 and the transistor M2. More specifically, the anode of the photodiode D1 is connected with the drain of the transistor M4. The gate of the transistor M4 is connected with the line RWS for supplying a read-out signal, and the source of the transistor M4 is connected with the gate of the transistor M2.

In the present embodiment, a node located between the photodiode D1 and the drain of the transistor M4 is referred to as the storage node INT. Thus, a node where the potential varies due to light current during a sensing period may be the storage node INT. The cathode of the photodiode D1 is connected with the line RWST.

Similar to the first embodiment, the line RWST supplies a reset signal and a read-out signal. The transistor M4 amplifies the potential VINT of the storage node INT during read-out. A read-out signal is supplied from the line RWS to the gate of the transistor M4 at the same time as a read-out signal is supplied to the line RWST. Thus, potential variations at the storage node INT during a sensing period between the supply of a reset signal and the supply of a read-out signal can be amplified to be read out. That is, the difference in the potential V_{INT} between any desired two points of time is amplified by the transistor M4. As a result, the “difference” in V_{INT} between brightness and darkness is amplified and output to the line OUT.

The transistor M4 of the present embodiment has the property of varying rapidly in electrostatic capacitance between before and after the threshold voltage of the gate. Thus, the capacitance of the transistor M4 can be dynamically varied using the potential of a read-out signal from the line RWS. That is, the transistor M4 functions as an amplifying element. The use of such a function of an amplifying element allows the photosensor of the present embodiment to amplify potential variations at the storage node INT during a sensing period and read it out.

Further, in the present embodiment, the boost-up of the potential V_{INT} during read-out is composed of both the boost-up from the line RWST via the photodiode D1 and the boost-up from the line RWS via the electrostatic capacitance of the transistor M4. Thus, the electrostatic capacitance of the transistor M4 is reduced. For example, as shown in FIG. 12, the capacitance of the transistor M4 is reduced compared with an arrangement where the potential V_{INT} of the storage node INT is boosted up and amplified during read-out using only the transistor M4.

This also reduces the capacitance C_{T} of the entire photosensor circuit, which further improves sensitivity. Sensitivity is also improved by the amplification effects from both the transistor M4 and the photodiode D1.

### Structure of Photosensor

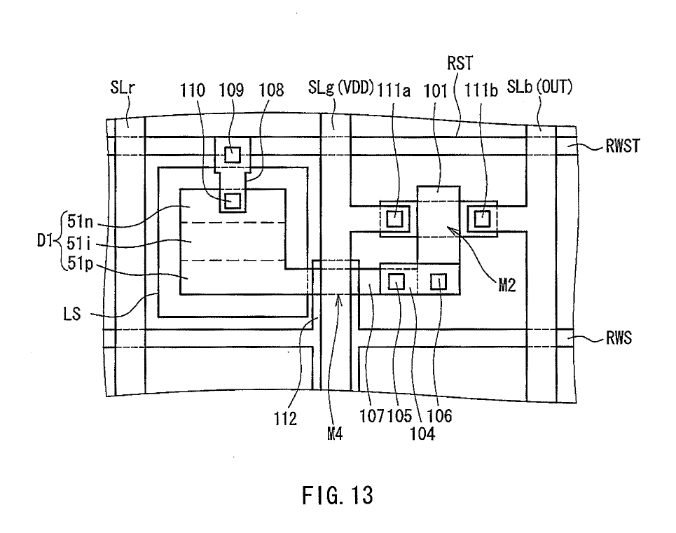

FIG. 13 is a diagram of an example of the structure of the photosensor shown in FIG. 11. In the implementation shown in FIG. 13, the photosensor includes, similar to the first embodiment, source metal forming the source lines SLr, SLg and SLb and gate metal forming the lines RWST and RWS that lie perpendicular to the source metal on the active matrix substrate. The source metal and the gate metal are formed as different layers separated by an insulating layer. In the implementation shown in FIG. 13, the gate metal is formed below the layer of source metal. The source line SLg also serves as a line VDD, while the source line SLb also serves as a line OUT.

The photodiode D1 is provided in the area sandwiched by the source line SLr and the source line SLg. The transistor M2 is provided in the area sandwiched by the source line SLg and the source line SLb. Similar to the first embodiment, the photodiode Di is a lateral PIN diode where a p layer 51p, an i layer 51i and an n layer 51n are formed in series in the silicon film.

A light shielding film LS is provided on the backside of the photodiode D1. The n layer 51n forms the cathode of the photodiode Dl. The n layer 51p is connected with the line RWST via the line 108 and the contact holes 109 and 110. The p layer 51p forms the anode of the photodiode D1. The p layer 51p is connected with the gate electrode 101 of the transistor M2 via an extension 107 of the silicon film, the contacts 105 and 106, and the line 104. The transistor M2 includes a gate electrode 101 and an electrode including a source electrode 111b and a drain electrode 111a and having a portion lying over the gate electrode 101.

A transistor M4, which is a p-channel TFT, is formed by the extension 107 of the silicon film extending from the p layer 51p of the photodiode D1 and the wide portion 112 of the line RWS extending to a position above and overlying the extension 107 with an interposed insulating layer (not shown). The portions of extension 107 and the wide portion 112 of the line RWS that lie over each other with an interposed insulating layer function as a variable capacitance. The capacitance of this variable capacitance is suitably the minimum in design rules (within design restrictions) because the major boost-up during read-out is performed via the photodiode D1 and thus a large capacitance of the variable capacitance is not required. Thus, amplification due to the transistor M4 is achieved while minimizing the capacitance CT of the entire photosensor, thereby realizing further improvement in sensitivity.

The first and second embodiments of the present invention have been described, however, the present invention is not limited to the above embodiments and various modifications are possible within the scope of the present invention.

For example, the above embodiments have illustrated arrangements where the lines VDD and OUT connected with a photosensor are also used as source lines SL. Such an arrangement has advantages that it has a high pixel aperture ratio. However, since this arrangement uses the lines for the photosensor as source lines SL, output data of the sensor circuit cannot be read out while a video signal for display using pixels is being applied to the source lines SL. Thus, a read-out signal for output data of the sensor circuit must be applied during a flyback period. Consequently, the lines VDD, VSS and OUT for the photosensor may be separate from the source lines SL. Such an arrangement has a low pixel aperture ratio. However, the lines for the photosensor can be driven independently from the source lines SL, and thus output data of the sensor circuit can be read out independently from the times of display using pixels.

Further, in the above embodiments, the light detection element is a photodiode. However, a phototransistor, for example, may be used as a light detection element. Also, the amplifying element does not have to be a p-channel transistor and may be a variable capacitor, for example.

The present invention is industrially useful as a display device having a sensor circuit in the pixel region of the active matrix substrate.

In the claims:

1. A photosensor comprising:
a light detection element connected to a storage node to convert received light into an electric current;
a conductive film that forms a parasitic capacitance between the light detection element and itself;
a control signal line that supplies the storage node, via the light detection element, with a reset signal for resetting a potential of the storage node and a read-out signal for outputting the potential of the storage node; and
a switching element connected with the storage node and an output line to output, to the output line, an output signal corresponding to the potential of the storage node in response to the read-out signal.

2. The photosensor according to claim 1, wherein the light detection element is a photodiode having a cathode connected with the control signal line and an anode connected with the storage node.

3. The photosensor according to claim 1, wherein the light detection element is a photodiode;
the photodiode includes a silicon film provided above the conductive film to be electrically insulated from the conductive film; and
a p-type semiconductor region, an intrinsic semiconductor region and an n-type semiconductor region are provided adjacent to one another along a surface of the silicon film in the silicon film.

4. The photosensor according to claim 1, further comprising an amplifying element provided between the storage node and the switching element to amplify the potential of the storage node in accordance with the read-out signal.

5. The photosensor according to claim 1, wherein at least a voltage level of the reset signal, a voltage level for reverse-biasing the light detection element from the reset signal until the read-out signal and a voltage level of the read-out signal are set as voltage levels on the control signal line.

6. The photosensor according to claim 1, wherein:
when the reset signal is supplied, the potential of the storage node is initialized and, when the supply of the reset signal is finished, the light detection element is reverse-biased;
when the read-out signal is supplied, the potential of the storage node changed by a charge accumulated in the parasitic capacitance of the light detection element from the time when the supply of the reset signal is finished until the read-out signal is supplied is boosted up; and
the potential of the storage node is boosted up by the read-out signal and thus the switching element becomes conductive to output, to the output line, an output signal corresponding to the potential of the storage node.

7. The photosensor according to claim 1, wherein the conductive film is a light shielding film for the light detection element.

8. A display device comprising the photosensor according to claim 1 in the pixel region of the active matrix substrate.

9. The display device according to claim 8, further comprising:
a counter substrate opposite the active matrix substrate; and
liquid crystal sandwiched by the active matrix substrate and the counter substrate.
